(19) United States
(12) Patent Application Publication
(10) Pub. No.: US 2013/0333617 A1
(43) Pub. Date: Dec. 19, 2013

(54) PLASMA PROCESSING APPARATUS

(71) Applicant: Hitachi, Ltd., Tokyo (JP)

(72) Inventors: Hiroyuki KOBAYASHI, Kodaira (JP); Tetsuya SUZUKI, Yokohama (JP); Mayui NOBORISAKA, Yokohama (JP); Hideyuki NAGAISHI, Hachioji (JP); Hisanori MATSUMOTO, Kokubunji (JP)

(21) Appl. No.: 13/916,820

(22) Filed: Jun. 13, 2013

(30) Foreign Application Priority Data
Jun. 15, 2012 (JP) 2012-135315

(51) Int. Cl. C23C 16/503

(52) U.S. Cl. CPC C23C 16/503
USPC 118/723 E

(57) ABSTRACT

A plasma processing apparatus is provided in which film formation to a part other than a process target is suppressed, and a film formation process to the process target can be uniformly performed. The plasma processing apparatus includes a high-frequency power supply for plasma generation, a surface discharge type discharge electrode including two kinds of electrodes in one dielectric surface of a dielectric layer. The process target is brought into close contact with a discharge-surface-side surface of the discharge electrode, and a plasma is generated in a vicinity of a front surface of the process target. When a height of a surface of the dielectric layer just above the electrode is H2, and a height of a surface of the dielectric layer between the electrode and the electrode is H1, H1>H2 is established.

### FIELD OF THE INVENTION

1. Technical Field

The present invention relates to a plasma processing apparatus for performing a film formation process by mainly using an atmospheric pressure plasma.

2. Related Art

In recent years, a technique to generate a plasma at atmospheric pressure is studied, and its application to the generation of a functional film, such as a Si thin film or a diamond-like carbon (DLC) thin film, the removal of organic materials on a material surface, surface reforming, sterilization and the like is widely studied. In this atmospheric pressure plasma process, when the plasma process is performed on a process target with an area larger than a certain area (for example, a substrate of 1 m×1 m), a dielectric barrier discharge is widely used. The dielectric barrier discharge is roughly classified into two types. One of them is disclosed in, for example, Patent Literature 1 and is a parallel flat plate type in which a dielectric is inserted between two parallel arranged metal plates. The other is disclosed in, for example, Patent literature 2, and two comb-shaped electrodes are arranged in one dielectric surface. This discharge electrode pattern is of a planar discharge type and is traditionally used for a plasma display panel. When the planar discharge type discharge electrode is used, and the thickness of a process target (substrate to be processed) is thin, and the material of the process target is a dielectric (insulator), the rear surface of the process target is brought into close contact with the discharge surface side of the discharge electrode, and a plasma can be generated on the front surface side of the process target (here, this type of discharge is called a substrate transparent surface discharge). In this type, the discharge electrode does not come in direct contact with the plasma. Thus, particularly in a film formation process using a deposition gas as a processing gas, the adherence of deposition to the discharge electrode can be suppressed, and the cleaning period of the discharge electrode can be prolonged. That is, the improvement in mass productivity can be expected. Besides, since the space above the front surface side of the process target is widely opened, the degree of freedom of supply of the processing gas is high, the processing gas can be uniformly supplied to the process target, and there is a merit that the thickness distribution of the film in the film formation process can be easily uniformed.

Patent Literature 1: JP-A-2005-135892

Patent Literature 2: JP-A-2006-331664

In the substrate transparent surface discharge, it is preferable that the rear surface of the process target and the discharge-surface-side surface of the discharge electrode are in close contact with each other, and there is no gap between them. However, when the film formation process is performed while the process target is moved (for example, Roll-to-Roll system in which the process is performed while the film (process target) is wound), a gap may be formed between the rear surface of the process target and the discharge-surface-side surface of the discharge electrode due to the movement of the process target, and at this time, a plasma discharge may occur in the gap (hereinafter, this discharge is called also a rear surface discharge). The plasma generated by the rear surface discharge heats the discharge electrode, and the high temperature discharge electrode may deform the substrate to be processed by heat. Besides, in a part where the rear surface discharge is generated, the intensity of plasma generated on the front surface of the substrate to be processed becomes weak, or no plasma is generated on the front surface side of the substrate to be processed.

### SUMMARY OF INVENTION

A typical configuration of the invention is as follows. That is, a plasma processing apparatus of the invention is a dielectric barrier discharge type plasma processing apparatus and includes a surface discharge type discharge electrode (discharge electrode plate) in which two kinds of electrodes (antenna and earth) are formed in one dielectric surface. A process target is brought into close contact with a discharge-surface-side surface of the discharge electrode, a plasma is generated in a vicinity of a front surface of the process target and a plasma process is performed. In the discharge electrode, a height (H1 of FIG. 2) of a dielectric layer surface between the electrode and the electrode (antenna and earth) is higher than a height (H2 of FIG. 2) of the dielectric layer surface just above the electrode (antenna and earth) of the discharge electrode.

According to the invention, plasma generation (rear surface discharge) in the gap formed between the discharge electrode and the substrate to be processed can be prevented, and uneven film formation, deterioration of the substrate to be processed, damage, change in quality and the like can be prevented.

### BRIEF DESCRIPTION OF DRAWINGS

FIG. 1 is a schematic view for explaining the whole structure of a plasma processing apparatus according to a first embodiment of the invention.

FIG. 2 is a view for explaining a sectional structure of a plasma discharge part according to the first embodiment of the invention.

FIG. 3 is a schematic view showing an electrode pattern of the plasma discharge part according to the first embodiment of the invention.

FIG. 4 is a schematic view for explaining a structure of the plasma processing apparatus according to the first embodiment of the invention when the plasma processing apparatus is seen in a transport direction of a process target.

FIG. 5A is a view for explaining a factor to cause rear surface discharge.

FIG. 5B is a view for explaining another factor to cause the rear surface discharge.

FIG. 6A is a schematic view for explaining a manufacturing method of a discharge electrode and showing a sectional structure in a state in which a conductive layer 54 of copper or the like is formed on the whole surface of a dielectric substrate 5-1.

FIG. 6B is a schematic view for explaining the manufacturing method of the discharge electrode and showing a sectional structure obtained by forming an electrode pattern as shown in FIG. 3 by etching or the like.

FIG. 6C is a schematic view for explaining the manufacturing method of the discharge electrode and showing a sectional structure obtained by forming a dielectric layer 5-2 by coating or bonding.

FIG. 6D is a schematic view for explaining the manufacturing method of the discharge electrode and showing a sectional structure obtained by forming a dielectric layer 5-3 only on a surface of the upper dielectric layer 5-2 between an electrode and an electrode.

FIG. 6E is a schematic view for explaining the manufacturing method of the discharge electrode and showing a sectional structure obtained by a method of grinding the dielectric (portion 60) just above the electrode by polishing after the structure of FIG. 6C is formed.

FIG. 6F is a schematic view for explaining the manufacturing method of the discharge electrode and showing a sectional structure obtained by forming a dielectric layer 5-3 above a portion between an electrode 4 and an electrode 4 after the dielectric layer 5-2 is once flattened by polishing.

FIG. 6G is a schematic view for explaining the manufacturing method of the discharge electrode and showing a sectional structure in which the dielectric layer 5-3 is formed above the portion between the electrode 4 and the electrode 4, so that a dielectric surface height H1 between the electrode 4 and the electrode 4 is comparable to a dielectric surface height H2 just above the electrode, and the dielectric surface structure close to that of FIG. 5B is obtained.

FIG. 6H is a schematic view for explaining the manufacturing method of the discharge electrode and showing a sectional structure in which the dielectric layer 5-3 is formed above the portion between the electrode 4 and the electrode 4, so that, even if the dielectric surface height H1 between the electrode 4 and the electrode 4 is lower than the dielectric surface height H2 just above the electrode, the difference between H1 and H2 is made as small as possible.

FIG. 7 is a schematic view for explaining a high-frequency power supply for plasma generation according to the first embodiment of the invention.

FIG. 8 is a schematic view of a booster circuit in the high-frequency power supply according to the first embodiment of the invention.

FIG. 9 is a schematic view for explaining another structure of the high-frequency power supply for plasma generation according to the first embodiment of the invention.

FIG. 10 is another schematic view of the booster circuit in the high-frequency power supply according to the first embodiment of the invention.

FIG. 11 is a schematic view for explaining the whole structure of a plasma processing apparatus according to a second embodiment of the invention.

FIG. 12A is a schematic view for explaining a structure, as seen from a discharge surface side, of a discharge electrode plate of a plasma processing apparatus according to a third embodiment of the invention in which gas holes are provided.

FIG. 12B is a schematic view for explaining a structure of a vicinity of a gas hole 61 in an A-A′ section of FIG. 12A in the discharge electrode plate of the plasma processing apparatus according to the third embodiment of the invention, in which the gas holes are provided.

FIG. 13A is a schematic view for explaining an undesirable case of a structure, as seen from a discharge surface side, of a discharge electrode plate of a plasma processing apparatus according to a comparative example of the third embodiment of the invention, in which gas holes are provided.

FIG. 13B is a schematic view for explaining an undesirable case of a structure of a vicinity of a gas hole in an A-A′ section of FIG. 13A in the discharge electrode plate of the plasma processing apparatus according to the comparative example of the third embodiment of the invention, in which the gas holes are provided.

### DESCRIPTION OF EMBODIMENTS

Hereinafter, embodiments of a plasma processing apparatus to which the invention is specifically applied will be described in detail referring to the drawings.

### Embodiment 1

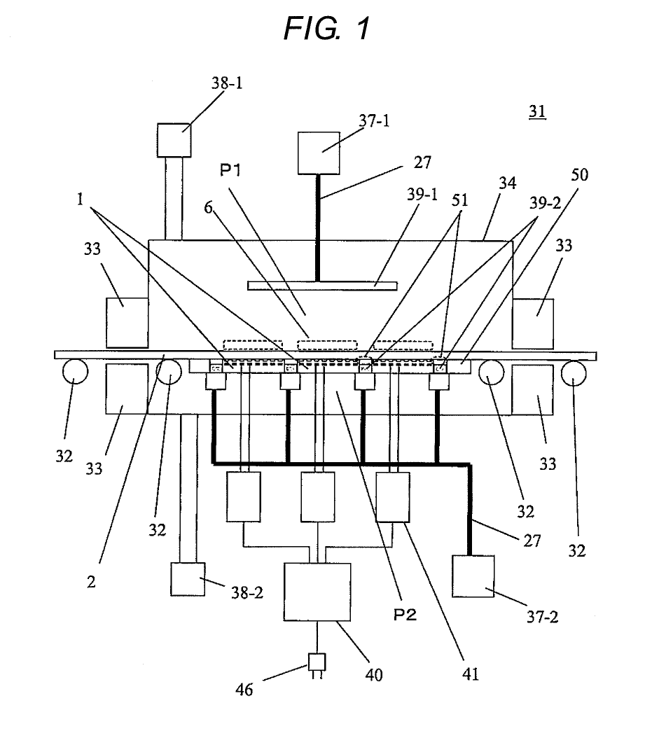

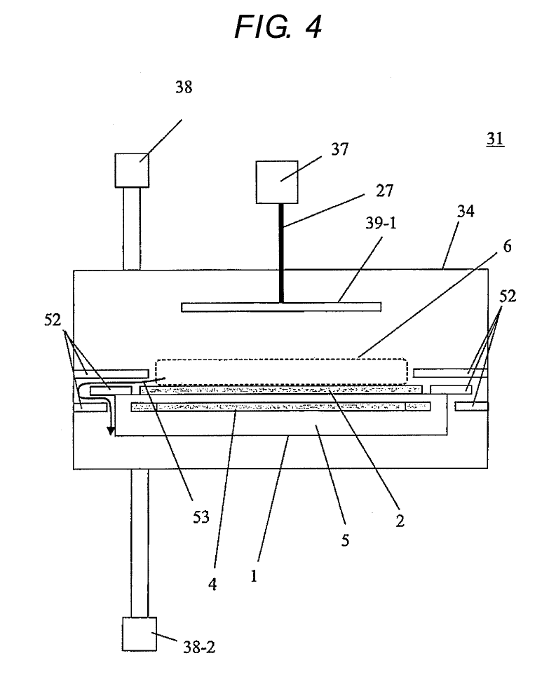

A first embodiment of the invention will be described with reference to FIG. 1 to FIG. 10. FIG. 1 shows an outline of a plasma processing apparatus 31 to which the invention is applied and which performs a film formation process on a process target at an atmospheric pressure. FIG. 4 shows the outline of the plasma processing apparatus of FIG. 1 when seen from a transport direction side of the process target (part of the illustration of FIG. 1 is omitted). Plural discharge electrode plates 1 for generating plasma are provided in a housing 34 forming a processing chamber. Rollers 32 are provided in the plasma processing apparatus 31 so that a rear surface side (surface on a side where a plasma process is not performed) of a process target (a substrate to be processed) 2 contacts the discharge electrode plate 1. A plasma 6 is generated above a front surface side (surface on a side where the plasma process is performed) of the process target 2. It is preferable that for example, a flexible dielectric (insulator) material such as a PET resin film or a hard dielectric (insulator) such as glass is used for the process target. When the flexible material is used as the process target, it is preferable to provide a device for winding the process target and a device for feeding the process target (transporting devices required in Roll-to-Roll processing system) (not shown) at both ends of the plasma processing apparatus 31.

A gas atmosphere switching device 33 for switching between a gas of a gas atmosphere inside the processing chamber and a gas of an air atmosphere outside the processing chamber is provided on an inlet side and an outlet side of the substrate to be processed. Besides, the plasma processing apparatus 31 includes a gas supply system 37-1 for supplying a processing gas and a gas supply system 37-2 for supplying a discharge suppressing gas to suppress generation of plasma (generation of rear surface discharge) in a gap formed between the rear surface of the process target 2 and the discharge electrode plate 1. A mixture gas in which Ar or He as a diluent gas is added to a gas of CxHy or SixHy, NH₃, H₂, N₂, etc. is used as the processing gas. For example, when a diamond-like carbon thin film is formed, the processing gas containing Ar/C₂H₂/H₂ mixture gas as its main component is used, and when a SiN film is formed, the processing gas containing He/SiH₄/H₂/NH₃ mixture gas as its main component is used. An N₂ gas is used as the discharge suppressing gas. Incidentally, the discharge suppressing gas is not limited to the N₂ gas, but may be any gas as long as the voltage required for discharge is higher than that of the processing gas. It is known that in general, a molecule containing a number of constituent atoms has a tendency that the voltage required to keep the discharge becomes high. For example, SF₆ (the number of atoms is 7) or C₃H₈ (the number of atoms is 11) can be used as the discharge suppressing gas.

The processing gas is supplied from a gas supply port 39-1 provided at a height position separate from the generation region of the plasma 6. The gas supply port 39-1 may include plural gas holes for gas supply or may supply the gas through a porous material. The discharge suppressing gas is supplied to a gap (groove) 51 formed between the discharge electrode plate 1 and the discharge electrode plate 1, or a gap (groove) 51 formed between the discharge electrode plate 1 and a height adjustment stand 50. By this, when the process target is transported, the discharge suppressing gas is supplied to the rear surface side of the process target.

The plasma processing apparatus 31 includes a gas exhaust system 38-1 for mainly exhausting a gas in a space above the process target 2 in the processing chamber and a gas exhaust system 38-2 for mainly exhausting a gas in a space below the process target in the processing chamber. Besides, a partition plate 52 is provided at a height position comparable to a height position of the process target in order to discriminate the atmosphere of the processing gas in the space above the substrate to be processed from the atmosphere of the discharge suppressing gas in the space below the substrate to be processed as much as possible. By this, the processing gas, which is liable to be discharged, can be prevented from entering the space formed between the substrate to be processed and the discharge electrode plate, and plasma is prevented from being generated in the space formed between the rear surface of the process target and the discharge electrode plate. When the pressure of the space above the substrate to be processed is P1, and the pressure of the space below the substrate to be processed is P2, P1>P2 (the pressure of the space below the substrate to be processed is relatively slightly negative pressure) is established in order to prevent the discharge suppressing gas from influencing the film quality in the film formation process. Besides, as shown in FIG. 4, it is not required that one partition plate 52 is provided at right and left sides, and plural partition plates are desirably provided so that a conductance to gas flow becomes small to a certain degree.

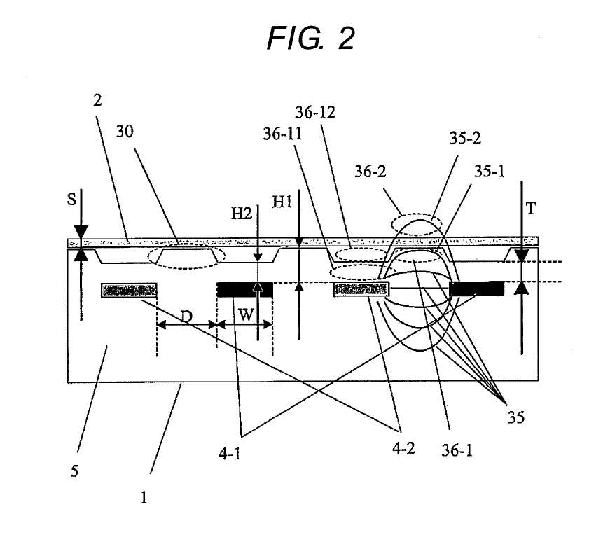

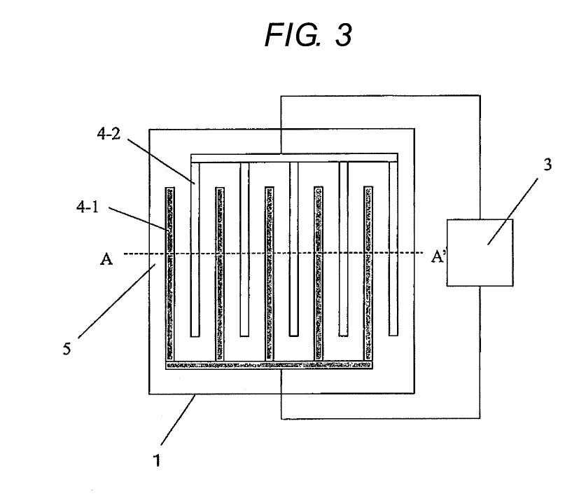

Next, the discharge electrode plate (hereinafter referred to also as a discharge electrode) 1 will be described with reference to FIG. 2 and FIG. 3. FIG. 3 shows an outline of a pattern of an electrode 4 when the discharge surface of the discharge electrode is seen from above. FIG. 2 is a schematic view for explaining a section of A-A′ of FIG. 3. The discharge electrode is constructed such that a comb pattern in which an antenna line (electrode 4-1) and an earth line (electrode 4-2) are alternately arranged is provided in a dielectric 5. The plasma is generated by an electric field of a space above the dielectric surface among electric fields (see electric force lines 35) formed between the antenna line and the earth line.

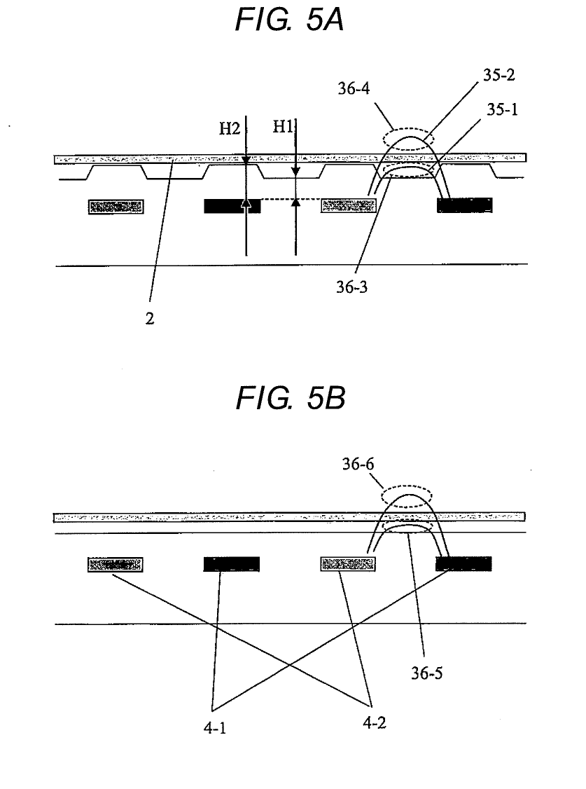

In this embodiment, as shown in FIG. 2, a concave-convex shape is formed on the dielectric surface of the discharge electrode plate 1. A height (H1) of the dielectric surface above a portion between the electrode 4-1 and the electrode 4-2 is higher than a height (H2) of the dielectric layer surface just above the electrode 4-1 or 4-2 as the antenna line or the earth line. The reason will be described below. For example, as shown in FIG. 5A, if the height H2 of the dielectric surface just above the electrode 4 is higher than the height H1 of the dielectric layer surface between the electrode and the electrode (H2>H1), since a space area 36-3 exists in the passage of an electric force line 35-1, a plasma may be formed here. Besides, when the plasma is generated in the space 36-3, an electric force line 35-2 passing through a space area 36-4 above the substrate to be processed is distorted into the same passage as the electric force line 35-1 so as to pass through the plasma, and the electric field intensity of the space area 36-4 is reduced. By this, in the space area 36-4 above the substrate to be processed, the intensity of the plasma is reduced, or the plasma is not generated. Besides, when the plasma is generated in the space area 36-3, the discharge electrode plate is heated by the plasma. In this case, the high temperature discharge electrode plate heats the substrate to be processed, and particularly when the substrate to be processed is made of resin, the process target expands or contracts, or a hole is formed. When the process target expands or contracts, a larger gap is formed between the rear surface of the process target and the discharge electrode plate. Thus, the structure of the dielectric surface of the discharge electrode shown in FIG. 5A is not desirable.

FIG. 5B shows a case where the surface of the discharge electrode plate is flat. In this case, if the rear surface of the process target is brought into close contact with the discharge electrode plate, the rear surface discharge is not generated. However, for example, when a flexible substrate such as a PET film is used as the process target, and the film formation process is performed while this process target is continuously transported, a gap is slightly formed between the rear surface of the process target and the discharge electrode plate due to the transport of the process target, and plasma may be formed between the rear surface side of the substrate to be processed and the discharge electrode plate. On the other hand, in this embodiment, as shown in FIG. 2, since the passage of the electric force line 35-1 is filled with the dielectric, plasma is not generated on the rear surface side of the process target, and plasma is stably generated in a space area 36-2 just above the front surface side of the process target. Besides, a space area 36-12 can serve as a gas supply route (flow path) for supplying the discharge suppressing gas. Besides, since the surface side of the process target has a slightly positive pressure as compared with the rear surface side of the process target, a force is exerted on the process target so that the process target is pressed to the surface side of the discharge electrode plate. Thus, when the concave-convex shape is formed on the surface of the discharge electrode plate, as compared with the case where the discharge electrode plate is flat, there is an effect that the force (adhesive strength) by which the process target presses the discharge electrode side is increased at the contact surface between the process target and the discharge electrode plate.

Besides, although the discharge suppressing gas is introduced to the rear surface side of the process target, a further reason why the electrode surface structure as shown in FIG. 2 is desirable will be briefly described below. For example, the electric field intensity of a space area 36-5 in FIG. 5B becomes higher than the electric field intensity of a space area 36-6 (or the electric field intensity of the space area 36-3 of FIG. 5A is higher than the electric field intensity of the space area 36-4). Thus, if a certain size of a gap is formed between the rear surface side of the process target and the discharge electrode, and the gas on the surface side of the process target and the gas on the rear surface side thereof are equal to each other in composition and pressure (or if the electric field intensity required for discharge is the same between both), as compared with the front surface side of the process target, plasma is formed preferentially on the rear surface side of the process target. Even if an electric field intensity (Ec) required for discharge of the discharge suppressing gas supplied to the rear surface side of the process target is higher than an electric field intensity (Ep) required for discharge of the processing gas supplied to the front surface side of the process target, if an electric field intensity (Eb) of the space between the rear surface side of the process target and the discharge electrode is further higher than an electric field intensity (Es) on the front surface side of the process target, the risk that the rear surface discharge is generated becomes high. That is, if

Ec−Ep<Eb−Es (1)

is established (if the difference between the electric field intensities on the rear surface and the front surface of the substrate to be processed is larger than the difference between the electric field intensities required for discharge of the discharge suppressing gas and the processing gas), the risk of the rear surface discharge becomes high. For example, in the case of Ep=Es as a minimum necessary condition for plasma generation on the front surface side of the process target, the expression (1) becomes Ec<Eb, and it is understood that the rear surface discharge is liable to be generated. Accordingly, in order to suppress the rear surface discharge,

Ec−Ep>Eb−Es (2)

is preferable. In general, since the voltage required for discharge in a noble gas is lower by a factor of several to ten than that in an N₂ gas. Thus, when the processing gas greatly diluted by the noble gas is used, if the N₂ gas is used as the discharge suppressing gas, the expression (2) may be relatively easily satisfied according to values of an inter-electrode gap D, the dielectric thicknesses H1 and H2, a thickness S of the process target and the like. However, as described before, since the rear surface side is made to have a negative pressure as compared with the front surface side of the substrate to be processed, part of the processing gas reaches the rear surface side of the substrate to be processed. As a result, when the processing gas, which is liable to be discharged, is mixed into the discharge suppressing gas, the effect of suppressing the rear surface discharge is reduced as compared with the case of only the discharge suppressing gas. Besides, in a molecule containing many atoms, such as SiH₄ or C₂H₂, as a raw material gas, the electric field intensity required for discharge is roughly equal to or higher than that of the case of the nitrogen gas. Thus, when the mixture ratio of the molecule containing many atoms is larger than the ratio of the noble gas, the difference of the electric field intensity required for discharge between the processing gas and the discharge suppressing gas becomes small, and it becomes difficult to satisfy the condition of the expression (2). Thus, it is desirable that in addition to the supply of the discharge suppressing gas, the concave-convex structure as shown in FIG. 2 is formed on the surface of the discharge electrode.

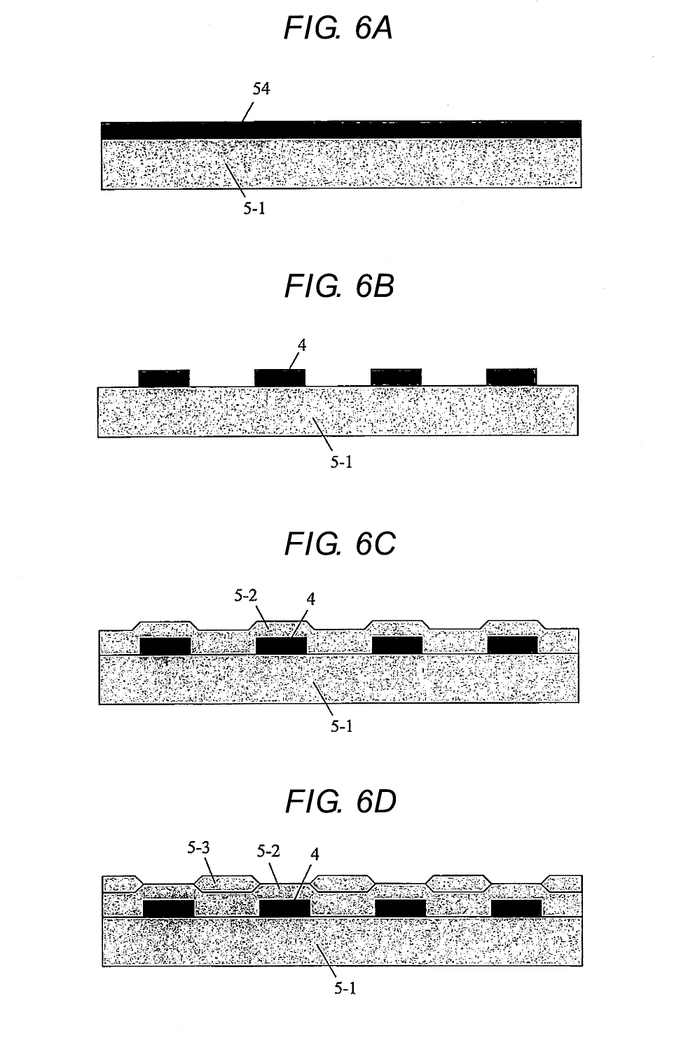

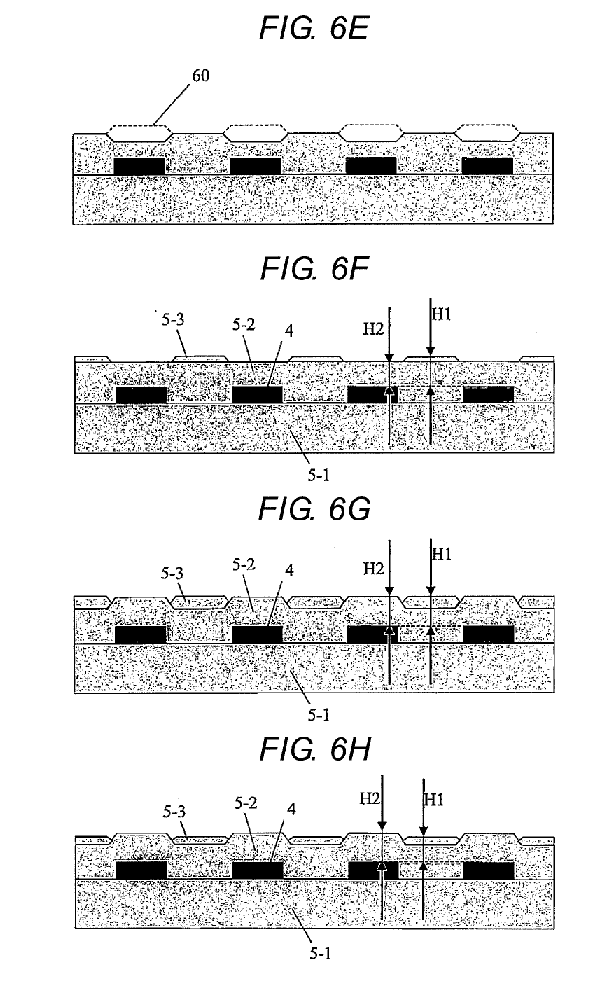

Next, a manufacturing procedure of the discharge electrode plate will be described with reference to FIGS. 6A to 6H. FIG. 6A shows a sectional structure in a state in which a conductive layer 54 of copper or the like is formed on the whole surface of a dielectric substrate 5-1. In this plate, the electrode pattern as shown in FIG. 3 is formed by etching or the like, and a sectional structure as shown in FIG. 6B is obtained. Next, a dielectric layer 5-2 is formed by coating or bonding (FIG. 6C). Incidentally, in FIG. 6C, concaves and convexes are formed on the surface of the dielectric layer 5-2 because of the thickness of the electrode 4. Next, a dielectric layer 5-3 is formed only on the surface of the dielectric layer 5-2 above a portion between the electrode and the electrode (FIG. 6D). By the procedure as stated above, the concave-convex structure of the discharge electrode surface as shown in FIG. 2 (state in which the dielectric surface height (H1) above the portion between the electrode and the electrode is higher than the dielectric surface height (H2) just above the electrode) can be obtained. Of course, after the structure of FIG. 6C is formed, as shown in FIG. 6E, a method of grinding the dielectric (portion 60) just above the electrode by polishing may be used. Besides, as shown in FIG. 6F, after the dielectric layer 5-2 is once flattened by polishing, the dielectric layer 5-3 may be formed above the portion between the electrode 4 and the electrode 4. It is desirable that the same dielectric material is used for the dielectric layers 5-1, 5-2 and 5-3 or materials close to each other in physical properties are used. As the dielectric material, for example, glass (quartz or sintered glass) containing SiO₂ as its main component or alumina containing Al₂O₃ as its main component is conceivable.

Incidentally, as shown in FIGS. 6A to 6C, according to the method in which the electrode pattern 4 is formed on the dielectric substrate 5-1, and the dielectric layer 5-2 is formed thereon, it is understood that there is a high possibility that the structure is generally formed in which the convex portion is formed just above the electrode as shown in FIG. 6C, that is, the most undesirable structure as shown in FIG. 5A is formed. Accordingly, when the structure as shown in FIG. 6C is formed, as shown in FIG. 6G, the dielectric layer 5-3 is formed above the portion between the electrode 4 and the electrode 4, so that the dielectric surface height H1 between the electrode 4 and the electrode 4 is comparable to the dielectric surface height H2 just above the electrode, and the dielectric surface structure close to that of FIG. 5B is formed. By merely doing this, there is a higher effect of suppressing the generation of plasma on the rear surface side of the process target than the structure shown in FIG. 6C. Besides, as shown in FIG. 6H, when the dielectric layer 5-3 is formed above the portion between the electrode 4 and the electrode 4, even if the dielectric surface height H1 between the electrode 4 and the electrode 4 is smaller than the dielectric surface height H2 just above the electrode, the difference between H1 and H2 is decreased as much as possible, so that there is a certain effect of suppressing the generation of plasma discharge on the rear surface side of the process target.

Next, the gap D between the electrode 4 and the electrode 4, the thicknesses H1 and H2 of the dielectric layer in the discharge electrode plate 1 shown in FIG. 2 will be described. First, from the viewpoint that plasma is generated on the front surface of the process target,

H1+S≦D/2 or H2+S≦D/2 (3)

is desirable. Incidentally, when consideration is given to the consumption or deterioration of the surface dielectric layer by the generation of rear surface discharge and discharge for cleaning of the discharge electrode plate (discharge in the state where the process target 2 does not exist on the discharge electrode plate 1), the right side of the expression (3) may be made a value larger than D/2, for example, D. However, if the value of the right side is excessively larger than D/2, it becomes difficult to generate a high electric field on the front surface side of the process target.

Besides, in order to prevent the breakdown of the discharge electrode plate, the electric field intensity in the dielectric in an area 36-11 of FIG. 2 must be smaller than the breakdown voltage of the dielectric. When the voltage of high-frequency power when the plasma process is performed is V (peak value (half value of Peak-to-Peak voltage)), and the breakdown electric field intensity of the dielectric 5 is Em, the height H2 is required to be determined so that

v/(2×H2)<Em (4)

is established (here, it is assumed that plasma is a resistance load and the resistance value is sufficiently small as compared with the impedance of the dielectric 5). For example, when the inter-electrode gap D is 1 mm, the thickness H2 of the dielectric layer is 0.1 mm, and the thickness S of the process target is 0.1 mm, and when He or Ar is the main component (when the concentration of other gases is several % or less), plasma can be generated on the front surface side of the process target by about 1 kV (when the frequency is on the order of kHz to several tens kHz). In this case, for example, when the breakdown electric field intensity Em of the dielectric 5 is 20 MV/m, from the expression (4),

H2>1 [kV]/20 [MV/m]/2=0.025 [mm]

is established, and it is understood that the breakdown does not occur when H2 is 0.1 mm. The height H1 is made a value slightly larger than H2, for example, a value larger than H2 by 0.01 mm to 0.05 mm. Of course, it is necessary to prevent the occurrence of such a case that the difference between H1 and H2 becomes excessively large and plasma is generated in the space area 36-12. When the thickness S of the process target is large, the inter-electrode gap 3, the dielectric layer thickness H2, and the applied voltage (discharge voltage) are made large. For example, when the thickness of the substrate to be processed is 0.5 mm, the inter-electrode gap is 5 mm, the thickness H2 of the dielectric layer is 0.5 mm, and the applied voltage is 5 kV. Besides, also in this case, the difference between H1 and H2 may not be necessarily increased, and may be made about 0.01 mm to 0.05 mm. The reason is as follows. That is, if the inter-electrode gap D is made large, the applied voltage (discharge voltage) V is required to be increased in proportion to that, and when the discharge voltage V is increased, H2 is also required to be increased in order to prevent breakdown of the dielectric layer. On the other hand, if the inter-electrode gap D, the discharge voltage V, and the thickness H2 of the dielectric are increased by similar scale factors, the electric field intensity distribution is not changed very much (here, it is assumed that the difference between H1 and H2 is sufficiently small as compared with H2 (H2−H1<<H2)). That is, if the electric field intensity in the gap between the rear surface side of the process target and the discharge electrode is not changed, the difference between H1 and H2 may not be changed.

Incidentally, in the calculation described above, it is assumed that the relative dielectric constant (∈2) of the process target is comparable to the relative dielectric constant (∈1) of the dielectric layer. When the difference between the relative dielectric constant of the process target 2 and the relative dielectric constant of the dielectric layer 5 is considered, in the above expression, S is replaced by S×∈1/∈2.

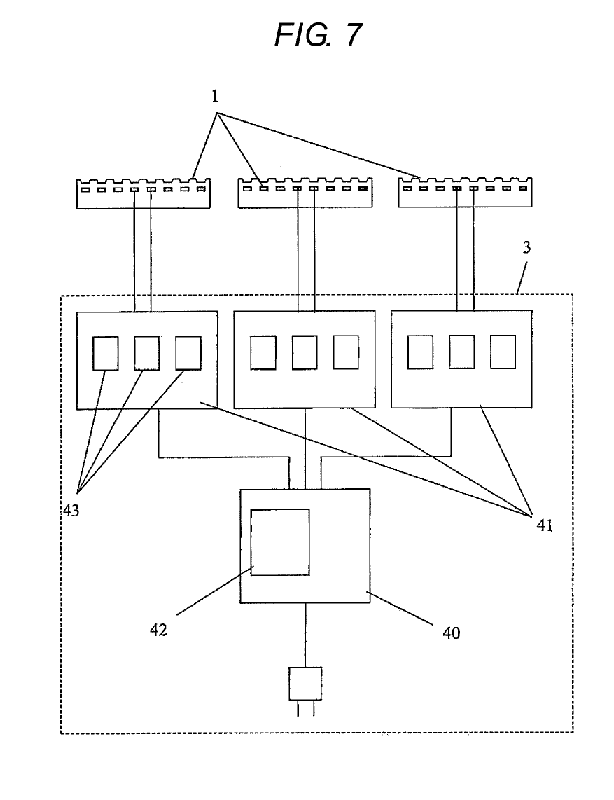

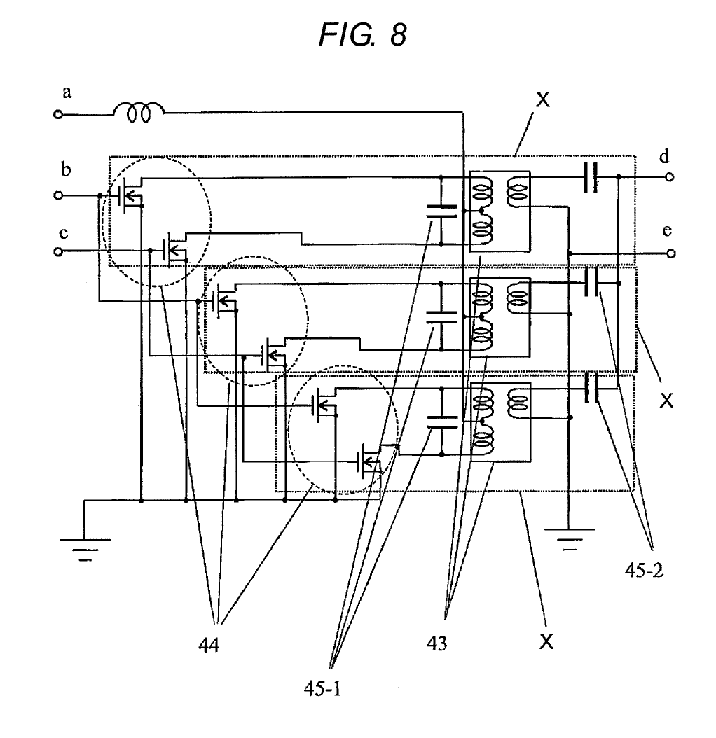

Next, a high-frequency power supply 3 for plasma generation in this embodiment will be described with reference to FIG. 7 and FIG. 8. The high-frequency power supply 3 includes a control circuit 40 and booster circuits 41. The one control circuit 40 is provided, and the number of the booster circuits 41 is equal to the number of the discharge electrode plates. The control circuit 40 includes a high-frequency signal circuit 42 for determining a frequency. A frequency signal outputted from the high-frequency signal circuit 42 is inputted to each of the booster circuits 41, and determines the frequency and phase of high-frequency power for plasma discharge generated in the booster circuit 41. By this, even if the plural booster circuits 41 are used and plasmas are generated by the plural discharge electrode plates 1, the discharge frequencies and the phases of the high-frequency powers are equal to each other.

Each of the booster circuits 41 can include one or plural booster coils 43. This is for increasing the output power of the one booster circuit 41, and the number of the coils mounted to the booster circuit 41 can be changed according to the discharge area or the like of the discharge electrode 1. FIG. 8 shows an outline of a circuit diagram of the booster circuit. In FIG. 8, “a” denotes an input terminal for DC power; “b”, an input terminal for a high frequency signal; “c”, an input terminal for a high-frequency signal of reverse phase to that at “b”; “d”, an output terminal for high-frequency power for plasma discharge; and “e”, an earth side terminal (connected to the earth line side of the discharge electrode plate). This circuit is constructed so that the plural booster coils 43 can be connected in parallel (the secondary sides of the plural booster coils are connected in parallel, and then are connected to the discharge electrode plate). That is, a circuit structure including the one booster coil 43, one capacitor 45-1 and one switching element pair (two FETs are used as one pair) is denoted by X, and plural such circuits X are connected in parallel. The input sides and output sides of the plural circuits X are respectively connected to each other. Incidentally, in FIG. 8, although a capacitor 45-2 is provided in each of the circuits X, the capacitor 45-2 may be provided at a point where the output sides of the circuits X are connected.

That is, in the structure shown in FIG. 7 and FIG. 8, the parallel connection of the plural coils in the booster circuit and the parallel connection of the plural circuits are enabled, so that the supply amount of power required for plasma generation can be easily increased in the case where the processing capacity is increased by increasing the discharge area of each of the discharge electrode plates or by increasing the number of the discharge electrode plates. Although the one booster circuit is connected to the one discharge electrode plate in FIG. 7, of course, the plural booster circuits 41 may be connected to the one discharge electrode plate.

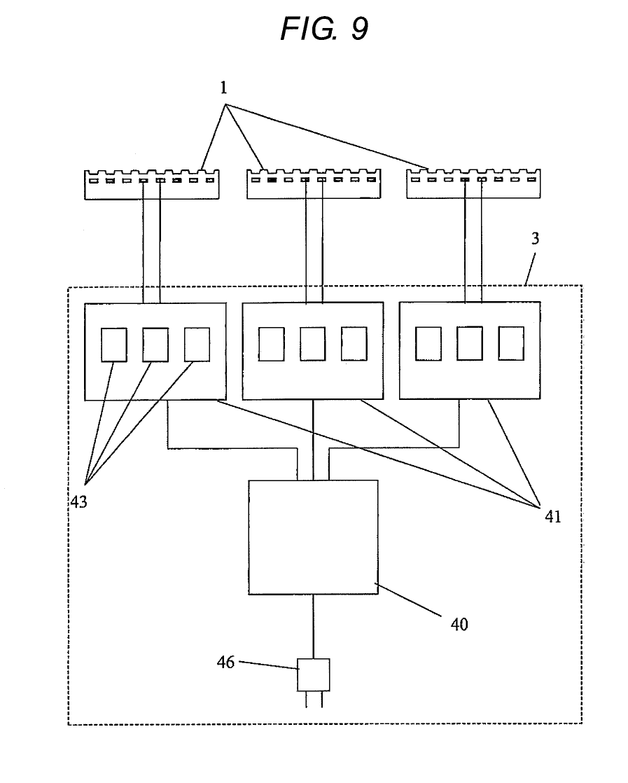

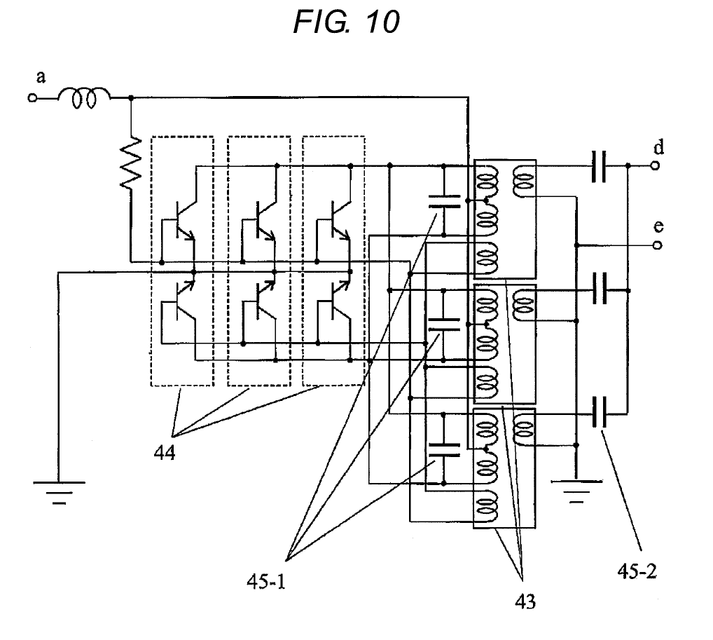

Incidentally, in the high-frequency power supply shown in FIG. 7 and FIG. 8, the one control circuit (high-frequency signal circuit) is connected to the plural booster circuits. However, as shown in FIG. 9 and FIG. 10, each of plural booster circuits may generate a high-frequency signal (may determine a frequency). Although FIG. 9 shows the same structure as FIG. 7, a control circuit 40 does not include a high frequency signal circuit 42, and its main function is to adjust the voltage of DC power to be supplied to the booster circuit. FIG. 10 is a schematic view of a booster circuit 41 of FIG. 9. Plural booster coils 43, plural capacitors 45-1 and plural switching transistor pairs 44 are provided. In this circuit, the frequency of the high-frequency power is mainly determined by LC resonance of the capacitor 45-1 and the booster coil 43. The switching transistor pair 44 uses two transistors as one pair, and the plural transistor pairs 44 are connected in parallel to each other. Besides, the plural capacitors 45-1 are provided and are connected in parallel to each other. The primary sides of the booster coils 43 are connected in parallel to each other, and the high voltage sides of the secondary sides are connected in parallel through capacitors 45-2. Incidentally, in the circuit of FIG. 10, the one switching transistor pair 44 is provided, or the one capacitor 45-1 is provided, and the plural booster coils 43 can be provided. However, in this case, in order not to change the frequency even if the number of the booster coils is changed, the capacity of the capacitor 45-1 is required to be changed. When the capacitors 45-1 whose number is equal to the number of the booster coils are provided, and the number of the coils is increased or decreased, if the number of the capacitors 45-1 is increased or decreased according to the number, the output power can be easily adjusted without changing the frequency of the high-frequency power. Besides, the reason why the number of the switching transistor pairs 44 is equal to the number of the booster coils is as follows. That is, when large power is supplied to the switching transistor, heat is generated and this causes heat loss, and therefore, the main object is to suppress the heat loss.

In the case of the high-frequency power supply 3 shown in FIG. 9, since the phases of the high-frequency powers outputted from the booster circuits are different from each other, the plural booster circuits can not be connected to the one discharge electrode plate 1. Besides, even when the one booster circuit 41 is connected to the one discharge electrode plate 1, if the distance between the plural discharge electrode plates 1 is small (distance between the generated plasmas is small), the output terminals (d of FIG. 10) of the booster circuits are connected (shorted) between the booster circuits through the plasmas. Thus, the installation distance between the discharge electrode plates is limited. On the other hand, there is a merit that the structure of the high-frequency power circuit is simple.

### Embodiment 2

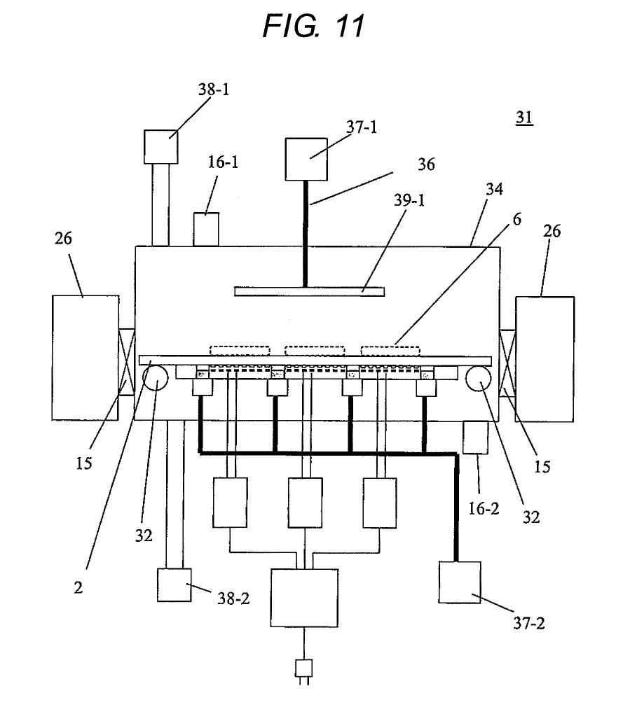

A second embodiment of the invention will be described with reference to FIG. 11. A description of the same components as those of the embodiment 1 will be omitted. In this embodiment, a plasma processing apparatus is shown which performs a film formation process in a reduced pressure state. A housing 34 for constituting a processing chamber is connected to another chamber 26. This chamber 26 may be a load lock chamber to switch between the air and reduced pressure atmosphere, or a processing chamber having the same function as the function of the housing 34, or a chamber to perform another process. The chamber 26 and the housing 34 are connected through a gate valve 15. A vacuum pump for reducing the pressure of the processing chamber is provided in an exhaust system 38-1 or 38-2. Besides, vacuum meters 16-1 and 16-2 for measuring the pressure in the processing chamber are provided. In the substrate transparent surface discharge system, not only in an atmospheric pressure atmosphere, but also in a reduced pressure atmosphere or a pressurized atmosphere, plasma can be generated on a front surface side of a substrate to be processed. Especially, in the reduced pressure atmosphere, there is a merit that the improvement of film quality in the film formation process is easy. On the other hand, if the processing pressure is excessively reduced, there is a possibility that the speed of a film formation process is decreased. Besides, as compared with the process at the atmospheric pressure shown in FIG. 1, the strength of the housing 34 is required to be increased, and the exhaust systems 38-1 and 38-2 require a large exhaust unit, such as a turbo molecular pump, which is required for vacuum exhaustion. Thus, there is a demerit that the whole plasma processing apparatus 31 becomes large.

### Embodiment 3

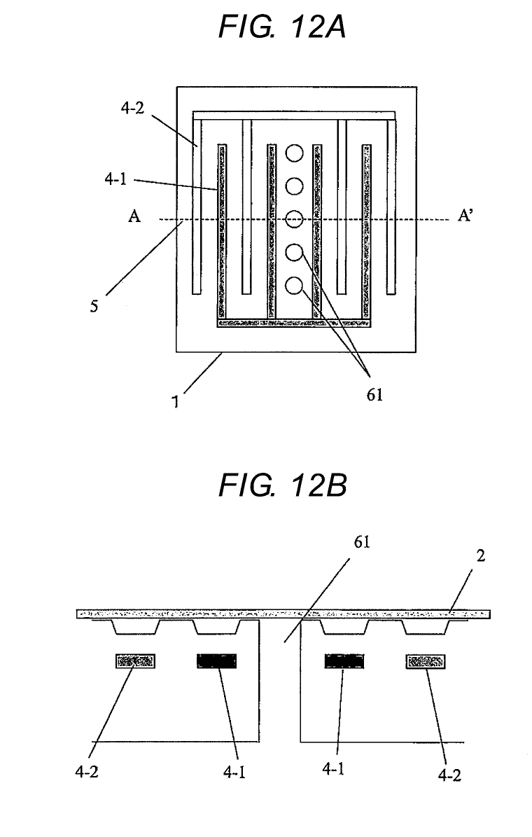

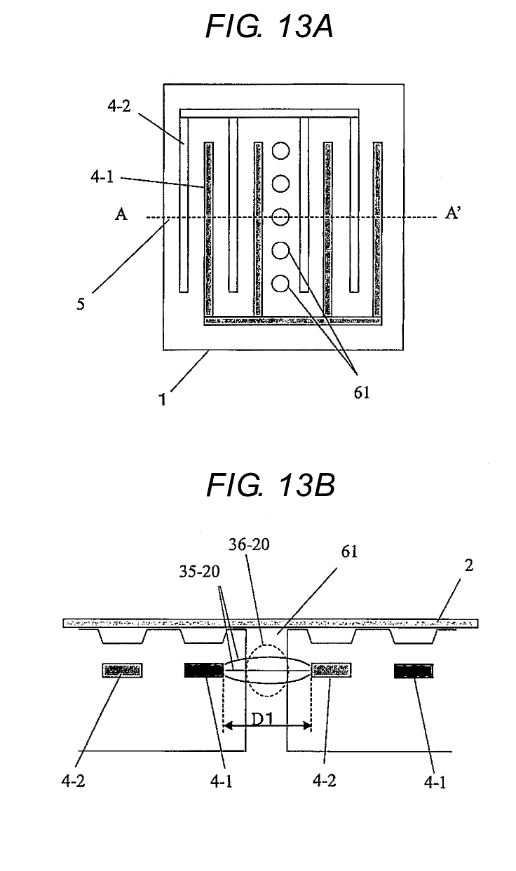

Although the embodiment 1 and the embodiment 2 have been described, a structure is shown in FIGS. 12A and 12B, in which gas holes are formed in the discharge electrode plate 1 used in the embodiment 1 and the embodiment 2. As shown in FIGS. 12A and 12B, gas holes 61 for releasing gas between a discharge surface side of a discharge electrode plate and a substrate to be processed may be provided in a surface of the discharge electrode plate. FIG. 12A is a view showing the structure when seen from the discharge surface side, and FIG. 12B is a view showing the structure near the gas hole 61 in an A-A′ section of FIG. 12A. The gas hole is provided between an electrode 4-1 and an electrode 4-1. Of course, the gas hole may be provided between an electrode 4-2 and an electrode 4-2. That is, the gas hole is desirably provided between an antenna line and an antenna line or between an earth line and an earth line. On the other hand, FIGS. 13A and 13B show an undesirable case of a structure in which gas holes are provided. As shown in FIGS. 13A and 13B (FIG. 13A shows the structure when seen from a discharge surface side, and FIG. 13B shows the structure near the gas hole in an A-A′ section of FIG. 13A), it is undesirable to provide the gas hole between an electrode 4-1 and an electrode 4-2, that is, between a pair of electrodes as an antenna line and an earth line. If a distance (D1 in FIG. 13B) between the antenna line and the earth line at both sides of the gas hole 61 is not sufficiently large, as shown in FIG. 13B, there is a fear that plasma is generated in an area 36-20 in the gas hole 61 by an electric force line 35-20 passing through the gas hole 61 among electric force lines generated between the antenna line and the earth line. This plasma causes a very strong discharge by hollow cathode effect or the like according to conditions of various sizes, discharge power, frequency of high-frequency power and the like, and there is a fear that a damage occurs in the discharge electrode plate or the substrate to be processed. Thus, in the case of the structure of FIGS. 13A and 13B, the distance W between the electrodes at both sides of the gas hole 61 must be increased. On the other hand, when the distance D1 is increased, the area of the discharge electrode is increased with that, and there occurs a demerit that the plasma processing apparatus 31 also becomes large.

Although the invention is described while using the plasma processing apparatus as an example, the invention may be applied to another process capable of performing a process using a plasma, such as cleaning, sterilization or surface reforming.

According to the invention, the generation of plasma in the gap formed between the discharge electrode and the substrate to be processed (rear surface discharge) can be prevented, and uneven film formation, deterioration of the substrate to be processed, damage, change in quality and the like can be prevented. Accordingly, the plasma processing apparatus can be provided in which film formation on a part other than the process target is suppressed, and the film formation process to the process target can be uniformly performed.

What is claimed is:

1. A plasma processing apparatus comprising:
a high-frequency power supply for plasma generation; and
a surface discharge type discharge electrode including two kinds of electrodes in one dielectric surface of a dielectric layer, wherein
a process target is brought into close contact with a discharge-surface-side surface of the discharge electrode,
a plasma is generated in a vicinity of a front surface of the process target, and
when a height of a surface of the dielectric layer just above the electrode is H2, and a height of a surface of the dielectric layer between the electrode and the electrode is H1, H1>H2 is established.

2. The plasma processing apparatus according to claim 1, wherein when a thickness of the dielectric layer just above the electrode is H2, a voltage of a high-frequency power applied to generate the plasma over the process target is V, and a breakdown electric field intensity of the dielectric layer is Em,
V/(2×H2)<Em
is satisfied.

3. The plasma processing apparatus according to claim 1, wherein a partition plate is provided in a processing chamber at a height position comparable to the process target.

4. The plasma processing apparatus according to claim 1, wherein the high-frequency power supply for plasma generation includes a booster circuit and a control circuit, the booster circuit includes a plurality of booster coils, and secondary sides of the plurality of booster coils are connected in parallel to each other and are connected to the discharge electrode.

5. The plasma processing apparatus according to claim 1, wherein a gas hole is provided between one of the two kinds of electrodes and an electrode of the same kind as the one.

6. A plasma processing apparatus comprising:
a high-frequency power supply for plasma generation; and
a surface discharge type discharge electrode including two kinds of electrodes in one dielectric surface of a dielectric layer, wherein
a process target is brought into close contact with a discharge-surface-side surface of the discharge electrode,
a plasma is generated in a vicinity of a front surface of the process target, and
the dielectric layer includes:
a first dielectric layer in close contact with a lower part of the electrode,
a second dielectric layer provided on one of the electrode and a surface of the first dielectric layer, and
a third dielectric layer provided on a surface of the second dielectric layer between the electrode and the electrode.

7. The plasma processing apparatus according to claim 6, wherein when a thickness of the dielectric layer just above the electrode is H2, a voltage of a high-frequency power applied to generate the plasma over the process target is V, and a breakdown electric field intensity of the dielectric layer is Em,
V/(2×H2)<Em
is satisfied.

8. The plasma processing apparatus according to claim 6, wherein a partition plate is provided in a processing chamber at a height position comparable to the process target.

9. The plasma processing apparatus according to claim 6, wherein the high-frequency power supply for plasma generation includes a booster circuit and a control circuit, the booster circuit includes a plurality of booster coils, and secondary sides of the plurality of booster coils are connected in parallel to each other and are connected to the discharge electrode.

10. The plasma processing apparatus according to claim 6, wherein a gas hole is provided between one of the two kinds of electrodes and an electrode of the same kind as the one.
